(19) United States
(12) Patent Application Publication
(10) Pub. No.: US 2025/0157903 A1
(43) Pub. Date: May 15, 2025

(54) Packaging module and manufacturing method therefor

(71) Applicant: Silergy Semiconductor Technology (Hangzhou) LTD., Hangzhou (CN)

(72) Inventors: Jian WEI, Hangzhou (CN); Ke DAI, Hangzhou (CN); Chao LI, Hangzhou (CN); Jiajia YAN, Hangzhou (CN)

(73) Assignee: Silergy Semiconductor Technology (Hangzhou) LTD., Hangzhou (CN)

(21) Appl. No.: 18/945,584

(22) Filed: Nov. 13, 2024

(30) Foreign Application Priority Data
Nov. 15, 2023 (CN) 2023115298313

(51) Int. Cl. H01L 23/498; H01L 21/48; H01L 21/56; H01L 23/29; H01L 23/492; H01L 23/64; H01L 25/16

(52) U.S. Cl. CPC H01L 23/49811; H01L 21/4853; H01L 21/56; H01L 23/293; H01L 23/492; H01L 23/645; H01L 25/16; H10D 1/20

(57) ABSTRACT

A packaging module and a manufacturing method therefor are provided. The packaging module includes a first packaging structure and a magnetic component. The first packaging structure includes a plastic packaging structure for encapsulating a non-magnetic component and metal connecting structures and exposing top surfaces of the metal connecting structures. The magnetic component is disposed above the first packaging structure includes terminal bond pads and a metal plating layer disposed between the metal connecting structures and the terminal bond pads. Vertical projections of the metal connecting structures and the terminal bond pads partially overlap on the horizontal plane. The metal plating layer contacts with the metal connecting structures and the terminal bond pads to form an electrical connection. The packaging module can enhance the reliability of soldering, further reduce the current impedance of the inductance, and decrease the thermal resistance from the inductance to the module output ground.

### FIELD OF THE INVENTION

The present disclosure relates to the field of semiconductor technology, specifically relates to a packaging module and a manufacturing method for the packaging module.

### BACKGROUND OF THE INVENTION

IC packaging power supply modules, due to their small size and high integration, are gradually starting to replace discrete solutions.

An IC packaging power supply module, as shown in FIG. 1a, includes a multilayer substrate 101, a bare die 102 disposed on the multilayer substrate 101, metal connecting structures 111 disposed on the multilayer substrate 101, an inductor 103, and terminal bond pads 112 disposed below the inductor. As shown in FIG. 1b, the size of the metal connecting structure 111 is limited by the layout dimensions of the bare die 102, preventing it from overlapping with the inductor terminal bond pad 112 in size. This leads to soldering reliability issues and affects the impedance from the inductor to the substrate, as well as the thermal conduction of the inductor downward.

### SUMMARY OF THE INVENTION

The present disclosure provides a packaging module. The packaging module includes a first packaging structure and a magnetic component. The first packaging structure includes a plastic packaging structure for encapsulating a non-magnetic component and metal connecting structures and exposing top surfaces of the metal connecting structures. The magnetic component disposed above the first packaging structure includes terminal bond pads and a metal plating layer disposed between each pair of adjacent metal connecting structures and the terminal bond pads, where vertical projections of the metal connecting structures and the terminal bond pads partially overlap on the horizontal plane. The metal plating layer is in contact with the metal connecting structures and the terminal bond pads, respectively, to form an electrical connection with each.

Preferably, a projected area of the metal plating layer in a vertical direction is greater than a projected area of the terminal bond pads in the vertical direction.

Preferably, a projected area of the metal plating layer in a vertical direction is greater than an area of top surfaces of the metal connecting structures.

Preferably, a projection of the metal plating layer basically completely overlaps with a combined projection of the metal connecting structures and the terminal bond pads in the vertical direction.

Preferably, the metal plating layer can be selected as either a single-layer metal or a multilayer stack including multiple metals.

Preferably, the metal connecting structures are disposed on two sides of the non-magnetic component.

Preferably, the magnetic component includes at least two terminal bond pads, and the number of the metal connecting structures is the same as the number of the terminal bond pads.

Preferably, the packaging module further includes a substrate. The non-magnetic component and the metal connecting structures are disposed on the substrate, where the non-magnetic component is electrically connected to the substrate.

Preferably, the non-magnetic component includes one or more of a bare die, a capacitor, and a resistor.

Preferably, the magnetic component includes an inductor or a transformer.

The present disclosure further provides a manufacturing method for a packaging module. The manufacturing method includes: forming a first packaging structure on the substrate, where the first packaging structure includes a plastic packaging structure for encapsulating a non-magnetic component and metal connecting structures and exposing top surfaces of the metal connecting structures; forming a metal plating layer on the first packaging structure that at least completely covers the metal connecting structures; and
providing a magnetic component on the first packaging structure, where terminal bond pads of the magnetic component are in contact with and electrically connected to the metal plating layer.

Preferably, the forming of the metal plating layer includes: depositing a single-layer metal or a multilayer metal stack on the first packaging structure by using an electroplating process.

Preferably, a projected area of the metal plating layer in a vertical direction is greater than a projected area of the terminal bond pads in the vertical direction or an area of top surfaces of the metal connecting structures.

Preferably, a projection of the metal plating layer basically completely overlaps with a combined projection of the metal connecting structures and the terminal bond pads in the vertical direction.

Preferably, the forming of the first packaging structure includes: providing the non-magnetic component on a substrate; electroplating metal connecting structures on two sides of the non-magnetic component; and encapsulating the non-magnetic component and the metal connecting structures by using the plastic packaging structure and exposing the top surfaces of the metal connecting structures.

Preferably, the providing of the magnetic component on the first packaging structure includes: soldering the terminal bond pads of the magnetic component to the metal plating layer by using surface mount technology to lead out electrodes of the magnetic component.

In the present disclosure, the packaging module is provided with a metal plating layer between the metal connecting structures of the first packaging structure and the terminal bond pads of the magnetic component, and the projection of the metal plating layers in the vertical direction basically completely overlaps with the combined projection of the metal connecting structures and the terminal bond pads in the vertical direction. This can increase the reliability of soldering and further reduce the current flow impedance of the inductor as well as the thermal resistance from the inductor to the module output ground.

### BRIEF DESCRIPTION OF DRAWINGS

The above and other objects, features, and advantages of the present disclosure will become more apparent from the following description of embodiments of the invention with reference to the accompanying drawings, in which:

FIG. 1a is a cross-sectional schematic diagram of a packaging structure of a power supply module in the prior art;

FIG. 1b is an enlarged schematic diagram of metal connecting structures of a power supply module and terminal bond pads of an inductor in the prior art;

FIG. 2 is a cross-sectional diagram of a packaging module according to one embodiment of the present disclosure;

FIGS. 3a to 3d are cross-sectional diagrams corresponding to certain steps of a manufacturing method for a power supply module according to one embodiment of the present disclosure.

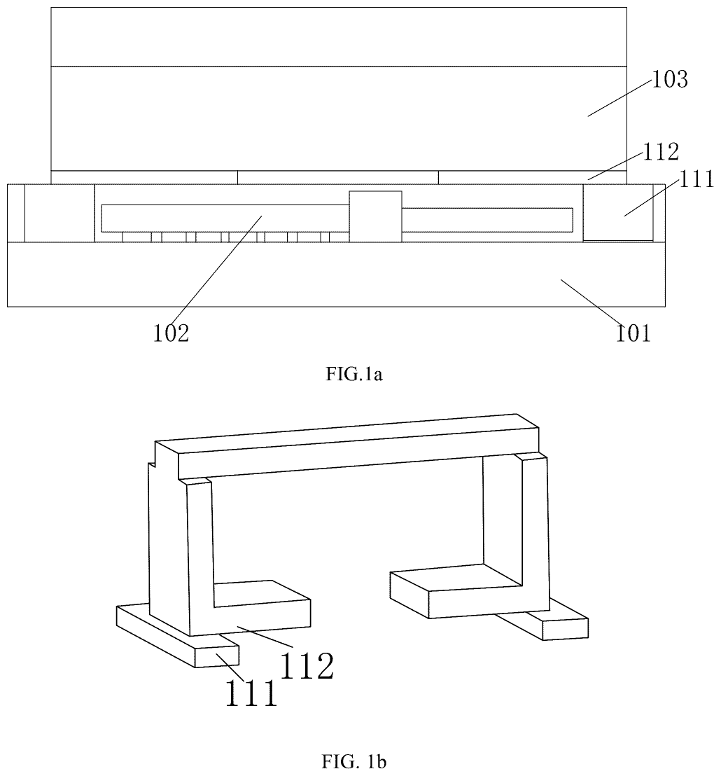

### DETAILED DESCRIPTION

The following describes the present disclosure based on the embodiments, but the present invention is not merely limited to these embodiments. The detailed descriptions of the present disclosure in the following elaborate on some specific details. Those skilled in the art can fully understand the present disclosure without the description of these details. Well-known methods, procedures, processes, components, and circuits are not described in detail to avoid obscuring the essence of the present disclosure.

In addition, the person skilled in the art should understand that the accompanying drawings are only for the purpose of illustration and are not drawn to scale.

At the same time, it should be understood that “circuit” in the following description refers to a conducting loop formed by at least one component or sub-circuit through an electrical connection or electromagnetic connection. When a component or a circuit is referred to as being “connected” to another component or the component/circuit is referred to as being “connected” between two nodes, it may be directly coupled or connected to another component or intervening component(s) may be present. The connection between the components may be physical, logical, or a combination thereof. On the contrary, when a component is referred to as being “directly coupled” or “directly connected” to another component, it means that there are no intervening component(s) present there between.

Unless otherwise required by the context, the terms “comprise”, “include” and the like used in the whole description herein and throughout the claims should be interpreted as inclusive meaning rather than exclusive or exhaustive meaning. In other words, the terms “comprise”, “include” and the like used in the whole description herein and throughout the claims should be interpreted as meaning “including but be not limited to.”

In the description of the present disclosure, it should be understood that the terms “first”, “second” and the like are only used for the purpose of explanation and should not be construed as indicating or implying relative importance. Additionally, in the description of the present disclosure, “multiple” means two or more unless otherwise specified.

A packaging module includes a first packaging structure and a magnetic component disposed above the first packaging structure. The first packaging structure includes a plastic packaging structure. The plastic packaging structure encapsulates a non-magnetic component and metal connecting structures, and exposes the top surfaces of the metal connecting structures. The magnetic component includes terminal bond pads and a metal plating layer disposed between each pair of adjacent metal connecting structures and the terminal bond pads, where vertical projections of the metal connecting structures and the terminal bond pads partially overlap on the horizontal plane. The metal plating layer is in contact with the metal connecting structures and the terminal bond pads, respectively, to form an electrical connection with each.

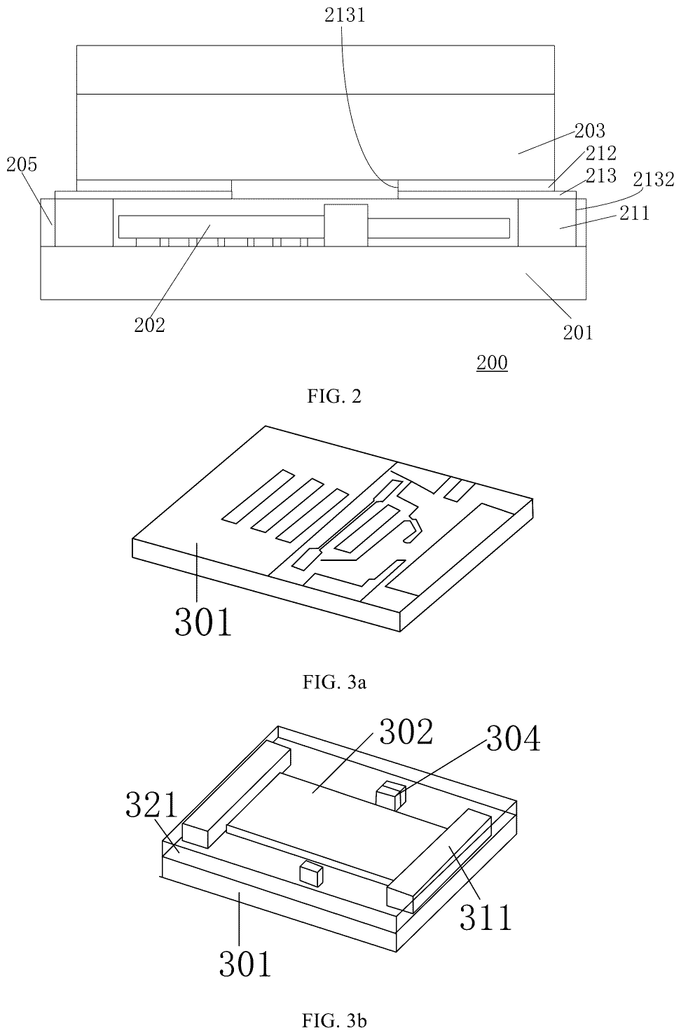

FIG. 2 is a schematic cross-sectional diagram of a packaging module according to one embodiment of the present disclosure. As shown in FIG. 2, the packaging module 200 includes a first packaging structure, a magnetic component, and a metal plating layer. The first packaging structure includes a plastic packaging structure 205. The plastic packaging structure 205 encapsulates a non-magnetic component 202 and metal connecting structures 211, and exposes the top surfaces of the metal connecting structures 211. The magnetic component 203 is disposed above the first packaging structure and includes terminal bond pads 212. The metal plating layer 213 is disposed between each pair of adjacent metal connecting structures 211 and the terminal bond pads 212. The vertical projections of metal connecting structures 211 and the terminal bond pads 212 partially overlap on the horizontal plane. The metal plating layer 213 is in contact with the metal connecting structures 211 and the terminal bond pads 212, respectively, to be electrically connected with the metal connecting structures 211 and the terminal bond pads 212.

The projected area of the metal plating layer 213 in the vertical direction is greater than the projected area of the terminal bond pads 212 in the vertical direction, and the projected area of the metal plating layer 213 in the vertical direction is greater than the area of the top surfaces of the metal connecting structures 211. Furthermore, the projection of the metal plating layer 213 in the vertical direction basically completely overlaps with the combined projection of the metal connecting structures 211 and the terminal bond pads 212 in the vertical direction. Specifically, a first side of the metal plating layer 213 aligns with a first side 2131 of each of the terminal bond pads 212, and a second side of the metal plating layer 213 aligns with a second side 2132 of each of the metal connecting structures 211. The first side and the second side of the metal plating layer 213 are opposite each other. Preferably, the metal plating layer 213 is made of copper material or may be other metals such as silver, nickel, tin, gold, etc., which is not limited herein. Furthermore, the metal plating layer 213 can be selected as either a single-layer metal or a multilayer stack including multiple metals.

The packaging module 200 further includes a substrate 201. The non-magnetic component 202 and the metal connecting structures 211 are disposed on the substrate 201. The non-magnetic component 202 is electrically connected to the substrate via a corresponding conductive connecting structure. The substrate 201 is provided as a multilayer substrate. Metal wirings are disposed both inside and on the surface of the multilayer substrate. The non-magnetic component 202 includes one or more of a bare die, a capacitor, and a resistor. The bare die, the capacitor, and the resistor can be disposed side by side on the substrate. Multiple metal connecting structures may be provided, and the metal connecting structures may be disposed on two sides of the bare die. In other embodiments, the metal connecting structures and the bare die may be disposed in different layers. The metal connecting structures can be provided above the bare die, and the specific location relationship is not limited. Preferably, the magnetic component 203 includes an inductor or a transformer and at least two terminal bond pads. The number of the metal connecting structures 211 corresponds to the number of the terminal bond pads 212, meaning that the counts of metal connecting structures 211 and the terminal bond pads 212 are the same. The metal plating layer 213 is disposed between each pair of adjacent metal connecting structures 211 and terminal bond pads 212.

The present disclosure further provides a manufacturing method for a packaging module. The method includes the following steps:
S1, providing a substrate, forming a first packaging structure on the substrate, where the first packaging structure includes a plastic packaging structure for encapsulating a non-magnetic component and metal connecting structures and exposing top surfaces of the metal connecting structures.

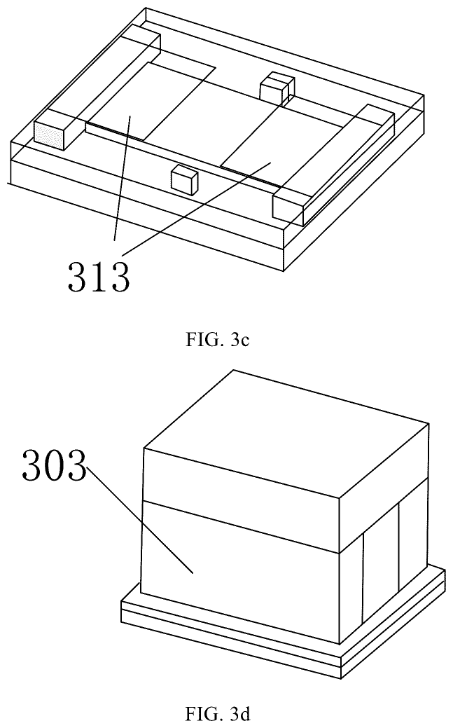

Specifically, as shown in FIG. 3a, a multilayer substrate 301 is provided, and the multilayer substrate includes multiple metal wirings disposed both inside and on the surface of the multilayer substrate.

As shown in FIG. 3b, a first packaging structure is formed on the substrate. A non-magnetic component and metal connecting structures 311 are first welded on the substrate, then the non-magnetic component and the metal connecting structures 311 are encapsulated by a plastic packaging structure 321, and the non-magnetic component may include one or more of a bare die, a capacitor, and a resistor. In one embodiment, the non-magnetic component includes a bare die 302 and capacitors or resistors 304 disposed on the front and behind sides of the bare die. In an example, the metal connecting structures are disposed on the left and right sides of the bare die 302.

In other embodiments, the metal connecting structures and the bare die may be provided in different layers. The metal connecting structures can be provided above the bare die, and the specific location relationship is not limited. The specific steps may include: forming a bare die on a substrate, encapsulating the bare die using a first encapsulation, then forming metal connecting structures on the first encapsulation, and encapsulating the metal connecting structures using a second encapsulation. Furthermore, a capacitor or an inductor may also be provided between the metal connecting structures on the first encapsulation. The plastic package structure 321 includes the first encapsulation and the second encapsulation.

S2: forming a metal plating layer on the first packaging structure that at least completely covers the metal connecting structures.

As shown in FIG. 3c, a metal plating layer 313 that at least completely covers the metal connecting structures is formed on the first packaging structure. Furthermore, the projected area of the metal plating layer 313 in the vertical direction is greater than the area of the top surfaces of the metal connecting structures. In order to better contact with the terminal bond pads of a subsequent magnetic component, the projected area of the metal plating layer 313 in the vertical direction is greater than the projected area of the terminal pads in the vertical direction. Furthermore, the projection of the metal plating layer 313 in the vertical direction basically completely overlaps with the combined projection of the metal connecting structures 311 and the terminal bond pads 312 in the vertical direction.

In one embodiment, a single-layer metal or a multilayer metal stack is deposited on the first packaging structure by using an electroplating process. The metal plating layer 313 is preferably made of copper or other metals such as silver, nickel, tin, and gold, which is not limited herein.

S3: providing a magnetic component 303 on the first packaging structure, where the terminal bond pads of the magnetic component 303 are in contact with and electrically connected to the metal plating layer.

As shown in FIG. 3d, the terminal bond pads of the magnetic component 303 are soldered to the metal plating layer by using surface mount technology to lead out the electrodes of the magnetic component 303.

The magnetic component 303 includes at least two terminal bond pads, and the number of the metal connecting structures 211 is configured to correspond to the number of terminal bond pads 212. The metal plating layer 313 is disposed between each pair of adjacent metal connecting structures 311 and terminal bond pads 312.

The preferred embodiments of the present disclosure are discussed above but are not used to limit the present disclosure. The person skilled in the art can make various amendments or modifications to the present disclosure. Any modification, equivalent replacement, improvement, etc. made within the spirit and principle of the present disclosure shall be within the protection scope of the present disclosure.

1. A packaging module, comprising:
a first packaging structure, which comprises a plastic packaging structure for encapsulating a non-magnetic component and metal connecting structures and exposing top surfaces of the metal connecting structures;
a magnetic component disposed above the first packaging structure, comprising terminal bond pads; and
a metal plating layer disposed between the metal connecting structures and the terminal bond pads,
wherein vertical projections of the metal connecting structures and the terminal bond pads partially overlap on the horizontal plane, and the metal plating layer is in contact with the metal connecting structures and the terminal bond pads, respectively, to form an electrical connection with each.

2. The packaging module according to claim 1, wherein a projected area of the metal plating layer in a vertical direction is greater than a projected area of the terminal bond pads in the vertical direction.

3. The packaging module according to claim 1, wherein a projected area of the metal plating layer in a vertical direction is greater than an area of top surfaces of the metal connecting structures.

4. The packaging module according to claim 1, wherein a projection of the metal plating layer basically completely overlaps with a combined projection of the metal connecting structures and the terminal bond pads in the vertical direction.

5. The packaging module according to claim 1, wherein the metal plating layer can be selected as either a single-layer metal or a multilayer stack comprising multiple metals.

6. The packaging module according to claim 1, wherein the metal connecting structures are disposed on two sides of the non-magnetic component.

7. The packaging module according to claim 6, wherein the magnetic component comprises at least two terminal bond pads, wherein the number of the metal connecting structures is the same as the number of the terminal bond pads.

8. The packaging module according to claim 1, further comprising a substrate, wherein the non-magnetic component and the metal connecting structures are disposed on the substrate, wherein the non-magnetic component is electrically connected to the substrate.

9. The packaging module according to claim 1, wherein the non-magnetic component comprises one or more of a bare die, a capacitor, and a resistor.

10. The packaging module according to claim 1, wherein the magnetic component comprises an inductor or a transformer.

11. A manufacturing method for a packaging module, comprising:
forming a first packaging structure, wherein the first packaging structure comprises a plastic packaging structure for encapsulating a non-magnetic component and metal connecting structures and exposing top surfaces of the metal connecting structures;
forming a metal plating layer on the first packaging structure that at least completely covers the metal connecting structures; and
providing a magnetic component on the first packaging structure, wherein terminal bond pads of the magnetic component is in contact with and electrically connected to the metal plating layer.

12. The method according to claim 11, wherein the forming of the metal plating layer comprises: depositing a single-layer metal or a multilayer metal stack on the first packaging structure by using an electroplating process.

13. The method according to claim 11, wherein a projected area of the metal plating layer in a vertical direction is greater than a projected area of the terminal bond pads in the vertical direction or an area of top surfaces of the metal connecting structures.

14. The method according to claim 11, wherein a projection of the metal plating layer basically completely overlaps with a combined projection of the metal connecting structures and the terminal bond pads in the vertical direction.

15. The method according to claim 11, wherein the forming of the first packaging structure comprises:
providing the non-magnetic component on a substrate;
electroplating the metal connecting structures on two sides of the non-magnetic component; and
encapsulating the non-magnetic component and the metal connecting structures by using the plastic packaging structure, and exposing the top surfaces of the metal connecting structures.

16. The method according to claim 11, wherein the providing of the magnetic component on the first packaging structure comprises: soldering the terminal bond pads of the magnetic component to the metal plating layer by using surface mount technology to lead out electrodes of the magnetic component.
